(19) United States
(12) Patent Application Publication
(10) Pub. No.: US 2010/0068105 A1
(43) Pub. Date: Mar. 18, 2010

(54) Microfluidic structures and how to make them

(75) Inventor: Gordon R. Green, BRISTOL (GB)

Correspondence Address: MORGAN, LEWIS & BOCKIUS, LLP. (PA), 2 PALO ALTO SQUARE, 3000 EL CAMINO REAL, SUITE 700, PALO ALTO, CA, 94306, US

(73) Assignee: AVIZA TECHNOLOGY LIMITED

(21) Appl. No.: 11/919,473

(22) PCT Filed: Apr. 25, 2006
(86) PCT No.: PCT/GB2006/001492

§ 371 Date: Mar. 19, 2008

Related U.S. Application Data
(60) Provisional application No. 60/674,710, filed on Apr. 26, 2005.

(30) Foreign Application Priority Data
Apr. 27, 2005 (GB) 0508488.4

(51) Int. Cl. B01J 19/00; B81C 1/00; B81B 1/00; B81B 7/00

(52) U.S. Cl. 422/189; 216/33; 216/41; 216/66; 216/67; 216/57; 216/83; 422/211

(57) ABSTRACT

A microfluidic structure includes a first layer (1) containing an active fluidic device (4); a second layer (3) containing an interconnect channel (6) for connecting the device (4) to a fluid source and/or outlet and/or another device and an intermediate layer (2) for defining at least one via (5) defining a fluid passage way between the device (4) and the interconnect channel (6) wherein the flow paths through the device (4) and the interconnect channel (6) are generally parallel.

### BACKGROUND

The miniaturization of fluid circuits is a field that has received considerable renewed interest in recent years. They were first developed for logic devices before the advent of solid state semiconductors and examples are U.S. Pat. No. 3,495,604 and U.S. Pat. No. 3,495,608. Here the logic and their interconnects are formed in a single surface of a single layer and sealed by a gasket or the backside of a further layer. More recently there has been renewed interest, particularly for the miniaturization of the analysis of fluids, thereby reducing sample size and enabling the possibility of using disposable analysis slides similar to credit cards mounted into point-of-use equipment. What has received less interest is the use of microfluidics for the manufacture of emulsions, polymer beads and the like whereby synthesis on the micro or nano-scale can be duplicated by massive parallelism to produce commercial quantities. There are many potential advantages including the mass production process being exactly the same as the research process and the possibility of extremely thorough mixing e g. to make an emulsion, without large energy inputs.

An example of manufacturing approach for multilayer microfluidics is shown at ENMA490 Fall 2003 University of Maryland to be found at:

http://www.mne.umd.edu/ugrad/courses/490 materials design/490 fall 2 003/enma490 fall2003 final project results/final-report-enma490-fall2003.pdf

This described a three dimensional interconnect structure with interconnects on two levels and vias in an intermediate level formed by moulding using PDMS and SU8 layers stacked onto a silicon wafer. This is an example of a strategy to use a base material such as silicon or glass that perhaps have certain desirable properties (e.g. toughness, cheapness, flatness) and then to add layers or selectively coat them with thin coatings or layers.

Another approach is to use a substrate of the desired material as in GB2395357A. Here a fluorinated polymer substrate is made and plasma etched to form structures. This is based on the semiconductor wafer model wherein a silicon wafer is used to form silicon devices. Whilst this approach ensures material integrity there are many problems with processing a polymer substrate. Another related approach is to form the structures in a base such as silicon and subsequently to coat their surfaces in such a way as to add surfaces that meet the requirements of the devices and interconnect layer surfaces in contact with the fluid(s) such as by coating with a fluorinated polymer. There are numerous problems associated with this approach, not least that coating a non-planar surface with well adhering, high quality and consistent thicknesses is presently difficult or impossible.

### SUMMARY OF THE INVENTION

The Applicants have appreciated that one more desirable manufacturing strategy is to use a prelaminated substrate and further laminate to form active device layers separated from interconnect levels, formed in a separate layer from the devices, and connect the devices to the interconnects by means of vias. For higher densities of devices stacking of multiple device levels and interconnect levels can be achieved to provide a compact and convenient high throughput array of large numbers of microfluidic devices.

It should further be understood that fluidic devices are extremely sensitive to surfaces including such characteristics as their energy level, smoothness/roughness, shape etc. The materials used should in most cases at least not contaminate the fluid(s) (unless desired), should be long lasting and preferably be standard materials that are already approved by regulatory authorities. So, for example the Applicants prefer Food and Drug Administration (FDA) approved materials for construction rather than easy to work materials that may then need coating to meet FDA or equivalent authority approval. It may however be desired to modify surfaces at least selectively to create turbulence, enable attachment of a functional component or in some way add or create functionality to the device.

The Applicants propose manufacturing or selecting a pre-manufactured substrate that consists of a laminate. This laminate consists of planar layers with significantly different properties with respect to a patterning process such as plasma etching. Some of the layer(s) may be either sacrificial and/or some may not materially contact the fluid(s) and therefore do not need to have desirable properties with respect to the fluid(s).

Processes well known e.g. to semiconductor wafer manufacture may be used to pattern devices in one face (upper) of the laminate and interconnect structures in another (lower) face. A gasket layer is then formed that may be a separate layer or part of the same laminate. Laminates are then stacked upon each other with an interposing gasket layer such that an upper device layer faces a lower interconnect layer with a gasket layer defining interconnects between the two.

It should be understood that a gasket layer can lie within the laminate between an upper and lower level of the same laminate.
It should further be understood that the channels thereby formed may be for constituent fluids, output fluids perhaps containing beads or droplets formed and fluids not directly part of the process such as to provide thermal control.

Thermal management of the process fluids within micro-fluidic devices is particularly applicable to polymeric substrates because of the low thermal conductivity of these materials. This at first seems counter-intuitive, but it is the low thermal conductivity which allows separate regions of a device to be maintained at different temperatures without excessively large heat fluxes. For example this concept would not be applicable to silicon-based devices. Although the heat exchanger structures described below would function on a silicon or glass based device, it would not be practicable to maintain separate regions of the same substrate at different temperatures.

The selection of hard mask layers that form part of the laminate that enable the successful processing of suitable materials for fluidic applications may be important. A preferable hard mask is conductive to enable electrostatic clamping to enable substrate backside pressurization to improve thermal conductivity to a thermally controlled substrate chuck.

The plasma etching of fluorinated polymers requires considerable ion bombardment as is described in GB2395357 and this creates heat that is not readily dissipated in a polymer substrate. The result is either melting of the polymer substrate, or much lower applied power levels resulting in a slow etch.

Electrostatic clamping without a conductive layer at the back or close to the back of the substrate is impossible and even mechanical clamping is of limited benefit as the heat input is from the plasma on the front face of the substrate and heat dissipation is largely from the back of the substrate to a chuck. Even running the chuck at extremely low temperatures is of limited value. GB'357 describes cryogenic cooling of a chuck, but without effective clamping of substrate to chuck and with a large thickness of polymer from front to back of the substrate, effective cooling is poor. Unfortunately the polymer has to be of a certain minimum thickness to have sufficient rigidity to remain flat and be handled. If the substrate is too thin it will not be flat and will therefore have even worse thermal conductivity to the cooled chuck and plasma processing is practically impossible.

Thus the Applicants may use a laminated substrate consisting in conductive and insulating polymer layers of less that 5 mm total thickness, preferably 3 mm or less thick and most preferable about 1.6 mm is selected. A suitable laminate is a PTFE microwave circuit board with metal, such as copper or nickel, on either or preferably both faces. To form devices on one face that face is patterned and etched as is well known in the art, preferably using the metal as a hard mask. The opposing face is patterned and etched with interconnecting structures.

It is then possible to pattern and etch vias connecting the devices on the one face to the interconnect structures on the other face, preferably from the interconnect side such that the substrate itself between device side and interconnect side is a gasket layer. Galleries through the substrate can also be formed that will interconnect the interconnect layers of stacks of substrates. Additionally or alternatively a gasket layer is formed and interposed between an upper and lower face of two substrates. Preferably this gasket layer is bonded to at least an upper or lower face of a substrate either before or after holes are formed in it that selectively connect devices to interconnect structures.

The devices and interconnects may be etched into the thickness of material and the etch process terminated by reference to time or an end-point signal. This endpoint may be achieved and etching slowed or terminated by using a laminate including a buried layer or layers that function as ‘etch stop’ layers. If such an etch-stop layer is used, this layer can remain or be (at least in part) removed by any suitable wet or dry process prior to use of the completed substrate. The selection of whether this ‘etch-stop’ layer remains is made on the basis of its suitability for the fluid it may be in contact with and the end application for the device. Reference may be made to lists of approved materials produced by relevant agencies, surface energy, fouling, leaching, absorption and in fact any relevant characteristic.

Devices may advantageously be laid out in vast numbers by using standard cell design rules as developed in the integrated circuit industry and it is therefore possible to package large numbers of active devices such as emulsifiers, mixers etc. onto a substrate. For example, with vias of 100×200 microns and a cell size of 200×600 microns with 2 emulsifiers per cell, 500,000 T branch emulsifier devices can be packaged onto a 200 mm substrate.

Suitable polymers for laminate layers and/or gasket layers include PTFE (PFA and FEP) as are supplied by DuPont including Teflon® and other polymers and metals that are generally considered to be ‘inert’ i.e. are inert enough for this application and service lifetime.

Conveniently PTFE is available bonded to metals including Nickel (both materials being Federal Drugs Administration approved) and copper from multilayer microwave circuit board suppliers such as Rogers Corp. This provides a relatively low cost, low risk route to enable the development of new structures.

### Constructing the Interconnect and Device Channels

A process flow may consist of the following:
1. Pattern interconnect (bottom) metal layer of a double sided ‘circuit board’ (copper/PFA/copper) and dry etch structures in PFA using the copper as a hard mask.
2. Repeat 1 for the device layer
3. Remove copper with a wet process
4. bond an FEP gasket layer to one face
5. Pattern and dry etch gasket layer
6. Drill galleries
7. bond stack

A preferred process sequence may be as follows:
1. Pattern interconnect (bottom) metal layer of a double sided ‘circuit board’ (copper/PFA/copper) and dry etch structures in PFA using the copper as a hard mask.
2. Remove copper from interconnect layer (e.g. with a spray wet process)
3. bond an FEP gasket layer to interconnect layer face
4. Pattern and dry etch gasket layer
5. Repeat 1 for the (top) device layer
6. Remove copper from device layer (e.g. with a spray wet process)
7. Drill galleries
8. bond stack

This second sequence may be preferable because it retains a copper conductor on the laminate (thereby enabling electrostatic clamping) for all dry etch processes.

The bonding may be by any suitable method including melting or cementing. In particular PTFE may be cemented (if treated) or thermally bonded.

There is a risk that during bonding the etched features may be at least partially filled by cement or melted material during the bonding process. This problem may be addressed by filling the etched structures with a sacrificial filler such as a soluble material before bonding and then dissolving out afterwards to ensure the bonding process does not fill the etched features.

Thus from one aspect the invention consists in a microfluidic structure having physically distinct layers including a first layer containing an active fluidic device, a second layer including at least one interconnect channel for interconnecting the device to a fluid source and/or outlet and/or another device and an intermediate layer for defining at least one via defining a fluid passageway between the device and the interconnect channel.

Preferably the structure further includes a plurality of devices in the first layer and a corresponding plurality of vias in the immediate layer. Further the structure may include a gallery passing through the interconnect channel for connecting the channel to other channels and/or a fluid source and for a fluid outlet.

The first and second layers may be formed of etchable polymer such as a fluorinated polymer or other suitable polymers can be used which can be otherwise patterned or can be imprint, moulded or otherwise shaped.

At least one of the first and second layers may include a labyrinth structure to enable local heating or cooling of a working fluid flowing through the structure. The labyrinth may be formed in part of an interconnect channel.

From a further aspect the invention consists in a microfluidic system including a stack of structures as defined above. In that case the stack may include a stack of planar elements having respective opposed faces with at least one interconnect channel in one of its faces and at least one device in the other of its faces, the elements being stacked with intermediate layers between them, so as to form the stack of structures. In an alternative embodiment the system may include a stack of planar elements having opposed faces wherein a first set of elements having at least one device formed in each of their faces and a second set of at least one interconnect channel formed in each of its faces, the elements from each set being stacked alternatively with intermediate layers between them so as to form the stack of structures.

From a still further aspect the invention includes a microfluidic element having a planar body with opposed faces and having one of the following combination of formations formed in its respective faces:
(a) both faces have at least one interconnect channel;
(b) both faces have at least one active device;
(c) one face has at least one interconnect channel and the other face has at least one active device.

From a still further aspect the invention includes a microfluidic apparatus including cartridges containing a plurality of structures as defined above, in which case the structures may form systems as defined above.

From a yet further aspect the invention consists in a microfluidic element having opposed faces including formations in each opposed face wherein the formations are of one of the following combinations:
(a) both faces have at least one interconnect channel;
(b) both faces have at least one active device;
(c) one face has at least one interconnect channel and the other face has at least one active device.

The substrate may initially be formed by a central etchable polymer layer with a metal layer on each of its opposed faces. In the method a first one of the metal layers may be patterned to form a hard mask and the associated face etched there through. Subsequently the substrate may be inverted and the second metal layer may be patterned and etched there through. The metal layers may be removed after etching.

It is particularly preferred that a metal layer is retained until all dry etching polymer is complete to allow electrostatic clamping of the substrate during the dry etch steps.

The method may further include drilling a gallery through at least one interconnect channel when such has been formed.

The substrate may include a central etch stop layer, which may be metal. The substrate may be formed of a fluorinated polymer.

The substrate may be patterned by alternate means to dry etching e.g. by embossing, moulding, selective curing/cross linking, ablation by laser, grit or water and the like and any other practicable method.

From a still further aspect the invention consists in a method of forming a microfluidic system including forming stacks of elements formed by any one of the methods set out above such that the face containing an interconnect channel faces a face containing a device except at the top and bottom of the stack and bonding via containing layers between them so that each device is connected to a facing interconnect channel by a via.

Prior to bonding the etching formations may be filled with removable, for example dissolvable, filler and the filler may be removed subsequent to bonding. This prevents the etched formations becoming blocked by the bonding material.

Although the invention has been defined above it is to be understood that it includes any inventive combination of the features set out above or in the following description.

The invention may be performed in various ways and specific embodiments will now be described, by way of example, with reference to the accompany drawings, in which:

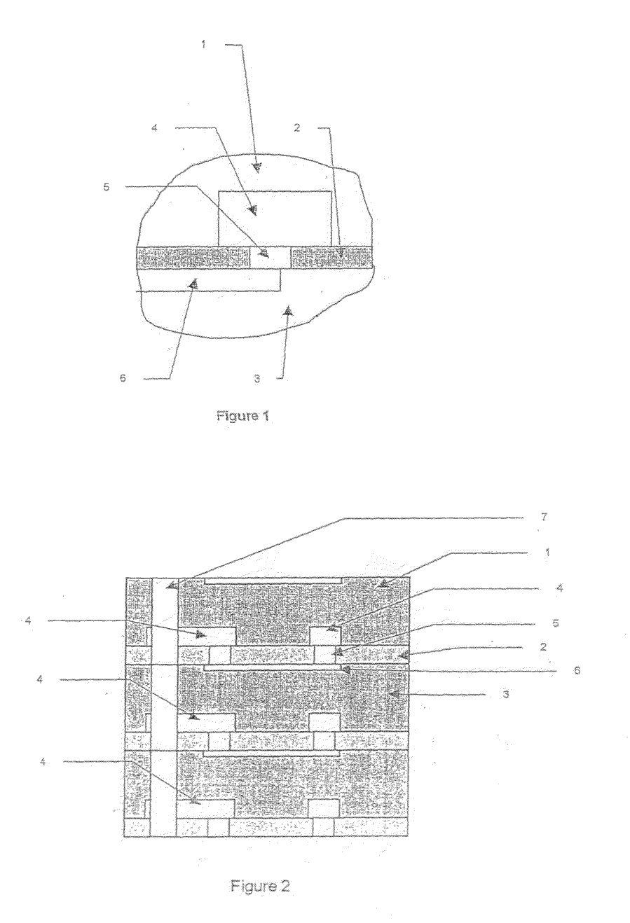

FIG. 1 is a cross section of a part of a competed structure of the invention

FIG. 2 is a cross section of a part of a stack of completed structures of the invention

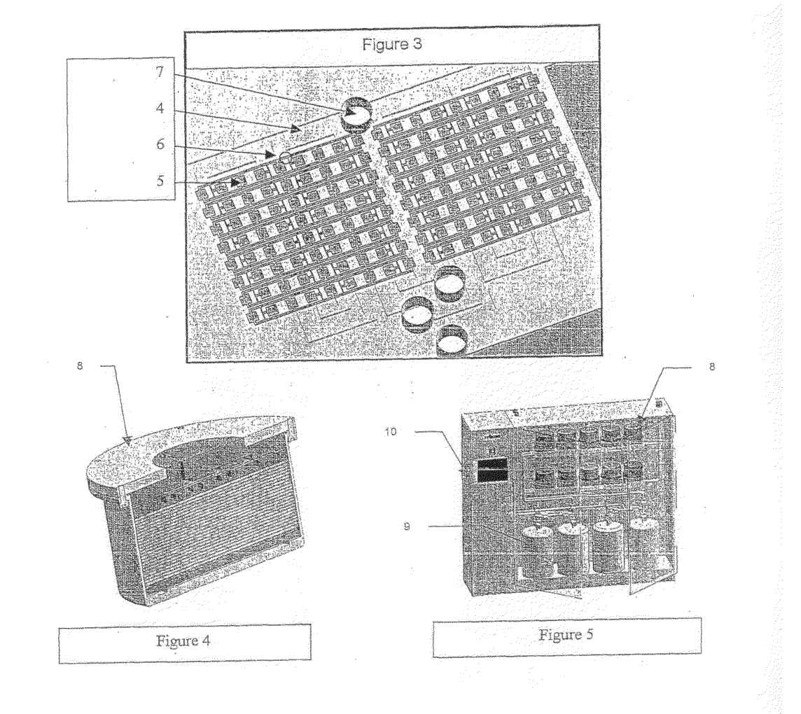

FIG. 3 is a ¾ semi-transparent view of ‘T’ emulsifier devices arranged 2 per cell and multiple cells per block

FIG. 4 is of a complete cartridge containing a stack of substrates

FIG. 5 is of a complete production system including multiple cartridges

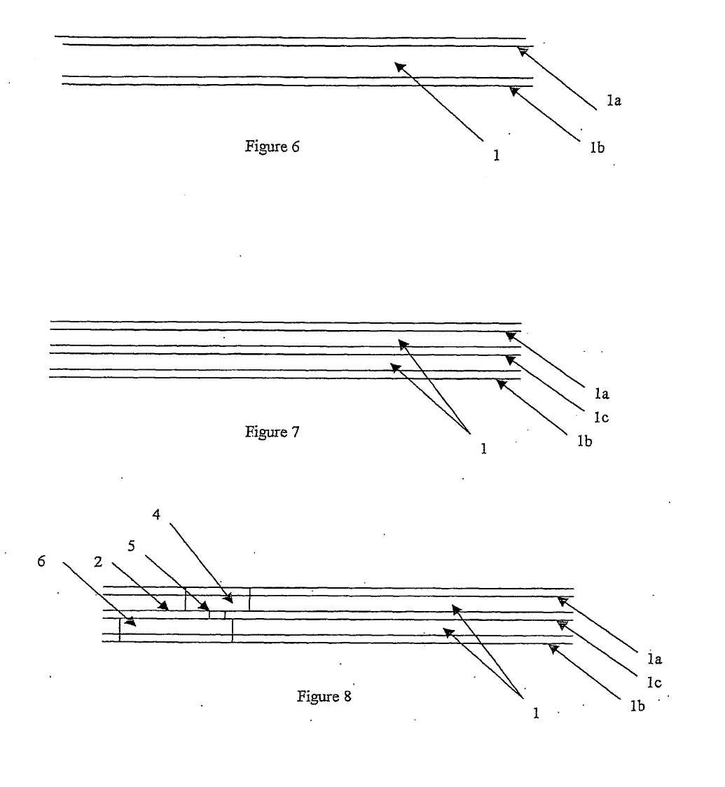

FIG. 6 is a cross section of a laminate before processing

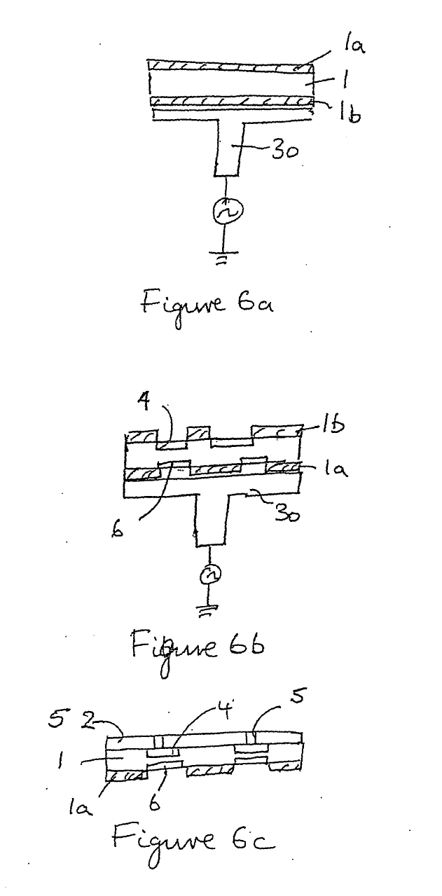

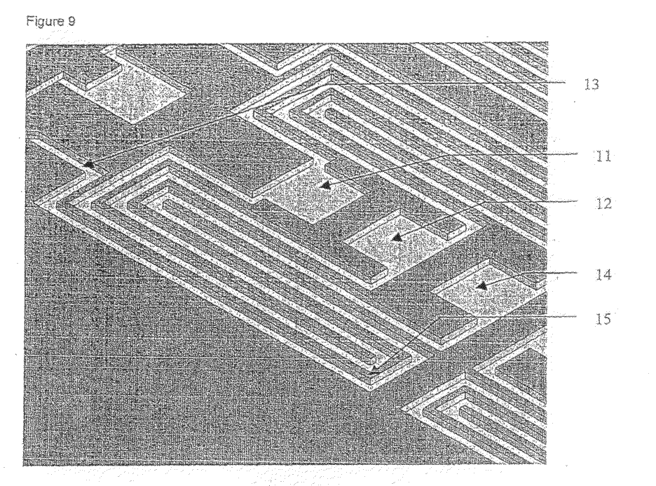

FIG. 7 is a cross section of another laminate before processing

FIG. 8 is a cross section of another laminate after processing

FIG. 9 is a heat exchanger

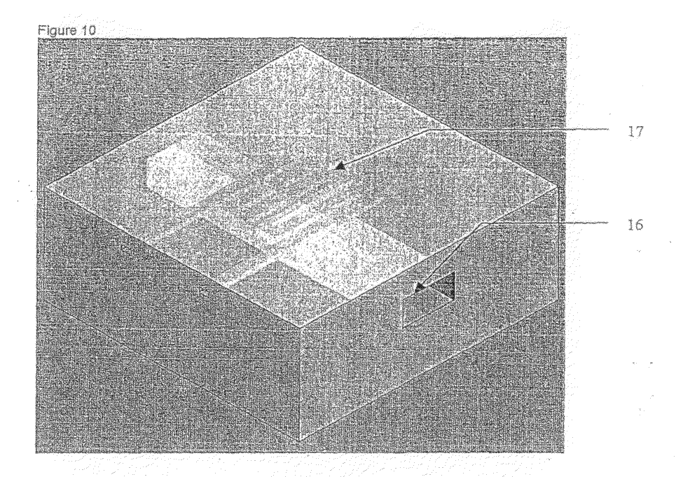

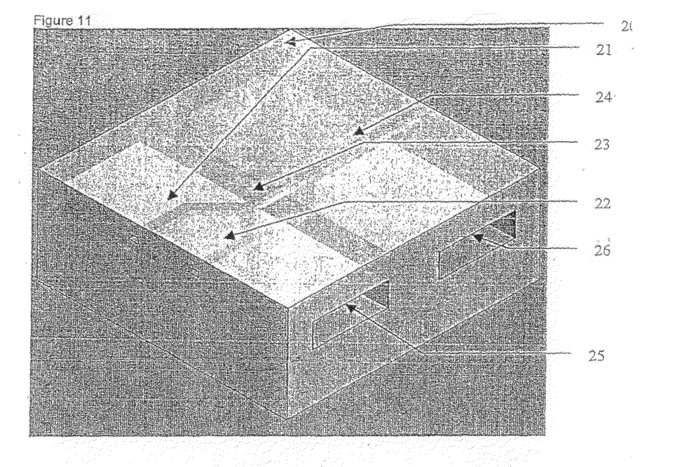

FIG. 10 is another heat exchanger

FIG. 11 is two heat exchangers

### DETAILED DESCRIPTION OF EMBODIMENTS OF THE INVENTION BY REFERENCES TO THE FIGURES

In FIG. 1 can be seen a top substrate 1 in which has been formed an interconnect channel 4. A gasket layer 2 with via 5 provides selective connection to a device 6 in a lower substrate 3.

In FIG. 2 a stack of substrates are diagrammatically represented with a gallery 7 connecting interconnect channels 4 of several stacked substrates.

In FIG. 3 can be seen a semitransparent ¾ view of a simple 3 terminal emulsifier made in 3 layers using 2 substrates. The gasket layer allows interconnect channels to pass over devices within the device layer allowing very high packing densities and arbitrary interconnect routing. By separating the interconnect layer from the device layer it become easier to form structures on different scale sizes. Typically interconnects will be very much larger, e.g. ten times larger than devices to minimise pressure drop in the interconnect channels and ensure even distribution and take up of fluids from the devices.

In FIG. 4 can be seen a completed and packaged cartridge 8 consisting in many substrates stacked together and encapsulated with suitable connections and fittings provided. These connections enable fluids to enter and leave the cartridge including temperature control fluid if required e.g. for a thermally induced polymerisation to create beads. Where local cooling is required cooling channels can run closely to where polymerisation is required. The poor thermal conductivity of fluorinated polymers means that the cooling is highly localized.

FIG. 5 shows a complete production system 10 including cartridges 8 and vessels 9 for collecting and feeding fluids to the cartridges 8 via suitable valving. The supply vessels may be pressurised to drive their fluids through the cartridge. Automated control systems such as a programmable logic controller (PLC) may be provided with a stored logic program, human interface and sensors, valves, flow measurers and controllers as appropriate. It may be valuable to have a sensor or sensors that monitor operation of the devices mounted in the cartridge by sensing the operation of at least one device on at least one substrate.

FIG. 6 is a cross section of a 3-layer laminate before processing. Substrate 1 has top and bottom layers 1a and 1b for example of copper. These layers have several functions and may be entirely sacrificial or at least in part remain on the substrate after processing. They enable electrostatic clamping and may act as a hard mask thereby enabling the dry etching of the substrate. Suitable etching processes include any suitable plasma source and substrate platen biasing as is well known in the field of dry etching. These are variously known as ‘RIE’ ‘ICP’ ‘diode’ ‘triode’ etc. PTFE consists entirely of fluorine and carbon and is difficult (but not impossible) to chemically etch. A dry process with aggressive ion bombardment is therefore preferred and inert gasses such as argon, krypton or xenon may be used in addition to a mix of carbon tetrafluoride and or sulphur tetrafluoride and oxygen. It should be noted that an advantage of a metal hard mask is that a photoresist mask may firstly be used to pattern the layers 1a and 1b and these layers be etched by any suitable means including wet etching with high selectivity to the underlying substrate 1. The layers 1a and 1b, with the photoresist mask still remaining, or removed may then be used as a robust mask for the etching of the substrate 1.

In FIG. 7 is shown a 5-layer substrate with a further layer 1c before processing. Layer 1c may provide an etch stop layer for either the device layer or the interconnect layer or both within a substrate 1. The layer 1c may have characteristics of its own, particularly where exposed only to the device layer such as being a catalyst for a reaction and could be e.g. platinum, iron or any other catalyst. It may also form a gasket layer as is shown in FIG. 8.

FIG. 8 shows substrate 1 of FIG. 7 after completion of etching, but with both layers 1a and 1b still present for the sake of clarity. As can be seen, layer 1c has become gasket layer 2 with a via 5 etched therein. The upper part of the substrate contains interconnect channel 4 and in the lower substrate layer there is a device 5. Such a substrate could be used singularly or stacked with blanking sheets (with galleries only) to separate substrates from each other.

In FIG. 9 is shown a parallel micro-channel heat exchanger. Within a single layer micro-fluidic device, it is possible to construct parallel micro-channels between which useful quantities of heat can be transferred. FIG. 9 shows a typical parallel micro-channel heat exchanger etched into the surface of a PFA substrate. A temperature controlled coolant fluid enters the device at an inlet well 11 and flows via a serpentine micro-channel to outlet well 12. Product or supply fluid enters the heat exchanger via a second micro-channel at 13 and follows a parallel serpentine path to product outlet well 14. The product micro-channel and coolant micro-channel are separated by a relatively thin wall 15, through which heat is conducted. In the embodiment shown, the two micro-channels are 10 μm deep and 20 μm wide. The wall between the micro-channels is 5 μm thick. However a wide range of dimensions are possible. The thermal resistance between the two micro-channels is approximately 2×10⁵ K.W⁻¹ for a 10 μm length. This is sufficient to allow useful heat transfer between the two fluids.

The length of the heat exchanger required for a particular application will depend upon the temperature difference between the incoming fluids, the required temperature change in the product fluid, in addition to the flow-rate and specific heat capacity of the fluids. Useful devices could be made with lengths ranging from the order of 10× to several 100× the depth of the micro-channel. The device shown has a length of approximately 1700 um.

A further enhancement would be to run coolant ducts along both sides of the product fluid duct. This would approximately double the heat transfer rate to or from the product fluid.

Coolant fluid could be any liquid or gas. However water is preferred because of its low viscosity, high specific heat capacity and absence of toxicity and similar product compatibility issues.

Obviously, the heat exchanger can be used to either raise or lower the temperature of a product or supply fluid as required. An example application is the thermally induced solidification of a droplet into a bead in the output fluid.

FIG. 10 shows a multi-level heat exchanger. In micro-fluidic devices utilising more than one layer of ducting, an alternative heat exchanger construction is possible. Where two horizontal micro-channels are separated by a sufficiently thin vertical layer, then heat may be effectively transferred between those two micro-channels. The figure above shows a duct within a first layer 16 of a PFA substrate, which carries a temperature controlled coolant fluid. Product fluid flows through a serpentine duct 17 within a second layer immediately above the first layer. In the embodiment shown, the coolant duct 18 is 100 μm×50 μum in section and the product fluid duct 19 is 20 μm×10 μm in section. The vertical separation between the bottom of the product fluid duct and the top of the coolant fluid duct is 13 μm. The thermal resistance of this structure is approximately 2.6×10⁵ K.W⁻¹ per 10 μm length of overlapping product fluid duct, or a total of 4×10³ K.W⁻¹ for the structure shown.

As before, the detail design of the structure would depend on the flow rate and specific heat capacity of the product fluid and the required temperature changes. Other functionally equivalent (non-serpentine) layouts are possible and again double sided arrangements are conceivable.

More generally, thermal zones can be generated on the substrate by means of heat exchangers as is shown in FIG. 11.

A development of the heat exchanger principle is to engineer thermal distribution throughout an entire micro-fluidic substrate by means of single or multiple coolant circuits. If one or more reactants are required to be maintained at a first temperature prior to reaction and the product maintained at a second temperature during or after reaction, then this can be achieved by means of routing coolant ducts adjacent to the process fluid ducts so as to maintain differential temperatures within the substrate. This can be achieved using either the single layer or multiple-layer structures, or a combination thereof.
In the figure above, two reactant fluids flow in ducts 21 and 22, in a substrate 20 meeting and reacting at junction 23. The resulting product flows out through duct 24. Ducts 21 and 22 and junction 23 are maintained at a first temperature by means of proximity to a first coolant duct 25. After reaction, the product output stream is shifted to a second temperature by means of proximity to a second coolant duct 26.

Variations on the theme are conceivable. More than two zones of temperature control could be provided by means of additional coolant circuits. The detail design of the heat transfer zone in duct 24 above duct 26 could utilise a serpentine path, or run parallel, or be arranged in some other equivalent manner, according to the detail design requirement for thermal transfer. A similar result could also be achieved using parallel ducts in a single-layer implementation.

1. A microfluidic structure having physically distinct layers including a first layer containing an active fluidic device; a second layer including at least one interconnect channel for interconnecting the device to a fluid source and/or outlet and/or another device and an intermediate layer for defining at least one via defining a fluid passageway between the device and the interconnect channel characterised in the flow paths through the device and the interconnect channel are generally parallel.

2. A structure as claimed in claim 1 further including a plurality of devices in the first layer and a corresponding plurality of vias in the intermediate layer.

3. (canceled)

4. (canceled)

5. (canceled)

6. A structure as claimed in claim 1 wherein at least one of the first and second layer includes a labyrinth structure to enable local heating or cooling of a working fluid flowing through the structure.

7. A structure as claimed in claim 6 wherein the labyrinth is formed in a part of an interconnect channel.

8. A structure as claimed in claim 1 wherein the device and/or interconnect channel define flowpaths of substantially constant depth.

9. A microfluidic system including a stack of structures as claimed in claim 1.

10. A system as claimed in claim 9 including a stack of planar elements having respective opposed faces with at least one interconnect channel in one of its faces and at least one a device in the other of its faces, the elements being stacked with intermediate layers between them so as to form the stack of structures.

11. A system as claimed in claim 9 including a stack of planar elements having opposed faces wherein a first set of elements have at least one device formed in each of their faces and a second set with at least one interconnect channel formed in each of its faces, the elements from each set being stacked alternately with intermediate layers between them so as to form the stack of structures.

12. A microfluidic element having a planar body with opposed faces and having one of the following combinations of formations formed in its respective faces characterised in that one face has at least one interconnect channel and the other face has at least one active device.

13. Microfluidic apparatus including cartridges containing a plurality of structures as claimed in claim 1.

14. Apparatus as claimed in claim 13 wherein the structures form systems as claimed in claim 1.

15. A method of forming a microfluidic element having opposed faces including formations in each of the opposed faces of a substrate characterised in that one face has at least one interconnect channel and the other face has at least one active device.

16. A method as claimed in claim 15 wherein the substrate initially is formed by a central etchable polymer layer with a metal layer on each of its opposed faces.

17. A method as claimed in claim 16 wherein a first one of the metal layers is patterned to form a hard mask and the associate face is etched there through.

18. A method as claimed in claim 17 wherein the substrate is inverted and the second metal layer is patterned and etched there through.

19. A method as claimed in claim 18 wherein the metal layers are removed after etching.

20. A method as claimed in claim 19 wherein the first metal layer is retained until etching through the second metal layer is completed to allow electrostatic clamping of the substrate during both etch steps.

21. A method as claimed in claim 15 wherein any formation is formed in a single etch step.

22. A method as claimed in claim 15 including further drilling a gallery through at least one interconnect channel when such has been formed.

23. A method as claimed in claim 15 wherein the substrate includes a central etch stop layer.

24. A method as claimed in claim 23 wherein the etch stop layer is metal.

25. A method as claimed in claim 15 wherein the substrate is formed of a fluorinated polymer.

26. A method of forming a microfluidic system including forming stacks of elements formed by the methods of claims 15 such that a face containing a device except at the top and bottom of the stack and bonding via-containing layers between them so that each device is connected to a facing interconnect channel by a via.

27. A method as claimed in claim 26 wherein prior to bonding the etched formations are filled with sacrificial removable filler and the filler is removed subsequent to bonding.

28. A method as claimed in claim 27 wherein the filler is dissolvable and is dissolved subsequent to bonding.
